(19) United States
(12) Patent Application Publication
(10) Pub. No.: US 2023/0378905 A1
(43) Pub. Date: Nov. 23, 2023

(54) METHOD FOR ASSEMBLING A PHOTOVOLTAIC STRUCTURE OPERABLE ON AN AQUATIC SURFACE

(71) Applicant: ELECTRICITE DE FRANCE, PARIS (FR)

(72) Inventors: Rémi LE BERRE, MORET-LOING-ET-ORVANNE (FR); David BOUBLIL, ASNIERES SUR SEINE (FR); Romain POIVEY, PARIS (FR)

(73) Assignee: ELECTRICITE DE FRANCE, PARIS (FR)

(21) Appl. No.: 18/248,307

(22) PCT Filed: Oct. 8, 2021
(86) PCT No.: PCT/EP2021/077863

§ 371 Date: Apr. 7, 2023

(30) Foreign Application Priority Data
Oct. 9, 2020 (FR) 2010342

(51) Int. Cl. H02S 30/20; H02S 40/22; B63B 1/12; B63B 17/02; F24S 20/70

(52) U.S. Cl. CPC H02S 30/20; H02S 40/22; B63B 1/125; B63B 17/02; F24S 20/70; B63B 2035/4453

(57) ABSTRACT

A method for assembling an electricity production structure including a plurality of floating modules, each having a frame and at least one photovoltaic panel, the structure further including at least one tarpaulin stretched under the panels of the modules, the method includes the steps of: supplying a first module with at least one tarpaulin having a main direction and being fixed to said frame in an initial folded or rolled-up configuration enabling deployment of a length of the tarpaulin in the main direction starting from said initial configuration, positioning at least one additional module adjacent to the first module in the main direction of the tarpaulin, assembling the modules, and deploying, tensioning, and fixing each tarpaulin of the first module to the frame of a module other than the first module.

### FIELD OF DISCLOSURE

This application concerns a floating photovoltaic structure comprising a tarpaulin stretched under the photovoltaic panels of the structure, and the installation of such a structure on an aquatic surface.

### BACKGROUND

The market for the generation of electricity by floating photovoltaic installations is booming, with around 2GW of power installed between 2017 and 2020. Indeed, this technology offers many advantages, in particular the gains in efficiency of the photovoltaic panels due to the cooling provided by the aquatic environment, the reductions in unwanted algae growth or evaporation, or slower water flows in some aquatic environments. It also allows productive exploitation of an otherwise non-developable environment, as in the case of old coal mines which are flooded to allow deployment of floating power plants.

In this context, the Applicant has filed patent application no. FR1761770, which concerns a floating photovoltaic module comprising one or more two-sided photovoltaic panels, and a reflector device assembled on the frame of the module, making it possible to increase the albedo of the aquatic surface on which the module is placed and thus to increase the efficiency of the module's electricity production.

In one embodiment, the reflector device comprises one or more tarpaulins, which can be stretched over the module to help stabilize the module.

In this case, it is suitable to propose a method for installing one or more modules on the destination aquatic surface, which allows ensuring that the tarpaulin remains taut once on the water in order to optimize its efficiency. Indeed, a lack of tension can lead to the presence of pockets of water on the tarpaulins. This can cause the development of algae which can reduce the reflection of luminous flux on the tarpaulin and therefore the efficiency of the electricity production. This can also attract birds, whose presence and in particular whose droppings cause known problems for floating photovoltaic structures (shading, hot spots, corrosive attacks).

### SUMMARY OF DISCLOSURE

In view of the above, an object of the present invention is to propose a method for assembling a floating photovoltaic structure provided with a taut tarpaulin, which ensures the tension of the tarpaulin, in particular in the case where the structure is installed on an aquatic surface.

Another object is to provide a method of assembly that is simple and fast to implement.

Another object is to facilitate maintenance by facilitating access to the panels once the structure is installed on the aquatic surface.

Another object is also to respect the aquatic ecosystem.

In this regard, a method is proposed for assembling an electricity production structure capable of being installed on a destination aquatic surface, comprising a plurality of modules capable of floating, each module comprising a frame and at least one photovoltaic panel mounted on the frame, the structure further comprising at least one tarpaulin stretched under the photovoltaic panels of at least two adjacent modules, the method comprising:
supplying a first module comprising at least one tarpaulin fixed thereto, the tarpaulin having a length, in a main direction, that is greater than the length of one side of the frame of the first module, and being fixed to said frame in an initial folded or rolled-up configuration enabling deployment of a length of the tarpaulin at least in the main direction starting from said initial configuration,
positioning at least one additional module adjacent to the first module in the main direction of the tarpaulin,
assembling the additional module to the first module, and
deploying and fixing each tarpaulin of the first module to the frame of a module other than the first module, and tensioning each tarpaulin.

Advantageously, but optionally, the method for assembling a floating structure further comprises at least one of the following features.

In some embodiments, the method may further comprise installing the first module on the aquatic surface, the steps of positioning, assembling at least one additional module, and deploying each tarpaulin being carried out on said aquatic surface.

In some embodiments, the method may further comprise installing on the aquatic surface the structure obtained after tensioning each tarpaulin, or installing the assembly of the first module and of each additional module on the aquatic surface before each tarpaulin is deployed.

In some embodiments, each photovoltaic panel of each module is a panel comprising two electricity-producing faces that are opposite to each other, and each tarpaulin is reflective.

In some embodiments, in the initial configuration, the tarpaulin comprises a central strip fixed to the first module and the two ends of the tarpaulin are rolled up or folded, and the method comprises assembling at least one additional module on each side of the first module in the main direction of the tarpaulin, deploying each end of the tarpaulin, and fixing each end of the tarpaulin to a respective module.

In some embodiments, the attachment of a tarpaulin to the frame of a module is implemented without requiring holes in the frame.

In some embodiments, the first module comprises several tarpaulins fixed next to each other in a direction perpendicular to the main direction of each tarpaulin, and the method comprises deploying each of the tarpaulins in the common main direction of the tarpaulins.

In some embodiments, supplying the first module comprises:
supplying the frame of the first module,
fixing a portion of the tarpaulin to the frame of the first module, and rolling up or folding back at least one remaining length of the tarpaulin and maintaining the tarpaulin in this configuration, and
fixing each photovoltaic panel to the frame of the first module.

According to another object, also proposed is an electricity production structure capable of being installed on a destination aquatic surface, comprising a plurality of modules assembled to each other, each module being capable of floating on an aquatic surface and comprising a frame and at least one photovoltaic panel mounted on the frame, the structure further comprising at least one tarpaulin stretched under photovoltaic panels of at least two adjacent modules, the ends of each tarpaulin being fixed to different modules.

In some embodiments, this structure is obtained by implementing the method according to the above description.

In some embodiments, the tarpaulin can be reflective.

In some embodiments, each photovoltaic panel can comprise two electricity-producing faces which are opposite to each other.

In some embodiments, each tarpaulin is capable of supporting the weight of at least one operator.

In some embodiments, each tarpaulin is formed from a fabric comprising a set of regularly distributed through-holes adapted to transmit part of the light that is incident on the fabric.

In some embodiments, each tarpaulin and/or each module comprises fastening devices for fixing a tarpaulin to a frame without requiring holes, or tarpaulin tensioning devices.

According to another object, a floating photovoltaic power plant is also described, comprising at least two structures according to the above description, assembled together.

In some embodiments, the photovoltaic power plant further comprises at least one grating interposed between the frames of modules of two adjacent structures.

In some embodiments, the floating photovoltaic power plant may further comprise at least one gap having no tarpaulin, between the module frames of two adjacent structures.

According to another object, also described is an electricity production module able to float on an aquatic surface, the module comprising a frame, at least one photovoltaic panel mounted on said frame, and at least one tarpaulin fixed on the frame, the tarpaulin having a length, in a main direction, that is greater than the dimension of one side of the frame, being fixed to said frame in a folded or rolled-up configuration enabling deployment of a length of the tarpaulin in said main direction starting from said configuration.

The proposed method allows simplifying the assembling of a photovoltaic structure that can be operated on an aquatic surface, and ensuring the tension of the tarpaulin once the structure is on the water, by providing that a tarpaulin is pre-assembled to a module, and that this module is assembled to other modules on land, before deploying the tarpaulin and fixing it to the other modules. The same tarpaulin is fixed to at least two different modules, which simplifies the installation process by reducing the number of attachment steps, and by stabilizing the entire structure. In cases where the structure is operated on an aquatic surface, the first module and the additional modules can be placed on the water before assembling them and deploying the tarpaulin, which eliminates complex manipulations aimed at installing a complete pre-assembled photovoltaic structure on the aquatic surface.

In cases where the tarpaulin is reflective, and even more so when the modules are two-sided, it thus contributes to increasing the production efficiency of the photovoltaic structure.

In addition, the tension of the fabric thus obtained can allow operators to walk directly on the fabric to access the modules in a simple manner in order to carry out maintenance or repair operations. This allows eliminating the gratings or other walkways which are commonly used to enable personnel to access the photovoltaic panels, and therefore allows reducing the weight of the structure and its cost.

Large structures can thus be obtained, and the tarpaulins can be chosen in perforated or mesh fabric in order to allow some light to filter through and thus preserve the underlying aquatic environment.

### BRIEF DESCRIPTION OF THE DRAWINGS

Other features, details, and advantages will become apparent upon reading the detailed description below, and upon analyzing the appended drawings, in which:

FIG. 1a schematically represents an exemplary assembly of a first module with two other modules one on either side of the first.

FIG. 1b schematically represents the deployment of a tarpaulin over the assembly of modules of FIG. 1a.

FIG. 2a schematically represents another exemplary assembly of a first module to another adjacent module.

FIG. 2b schematically represents the deployment of a tarpaulin over the assembly of modules of FIG. 2a.

FIG. 2c schematically represents another embodiment of the assembly of two modules and the deployment of a tarpaulin.

FIG. 3 schematically represents a power plant obtained by assembling several structures.

FIG. 4a shows the insertion of twist-lock fasteners carried by a module, into eyelets arranged in a tarpaulin.

FIG. 4b shows rotation of the twist-lock fasteners to keep the tarpaulin fixed against the module.

FIG. 4c shows a tarpaulin provided with a U-bolt for its attachment to a tubular reinforcement element of a module, and a ratchet strap for tensioning it.

FIG. 5 shows the main steps of a method for installing a floating electricity production structure according to one embodiment.

### DETAILED DESCRIPTION

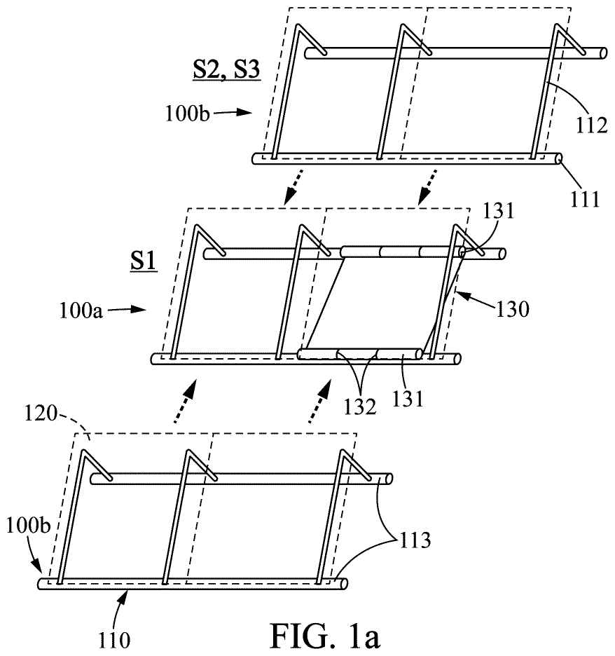

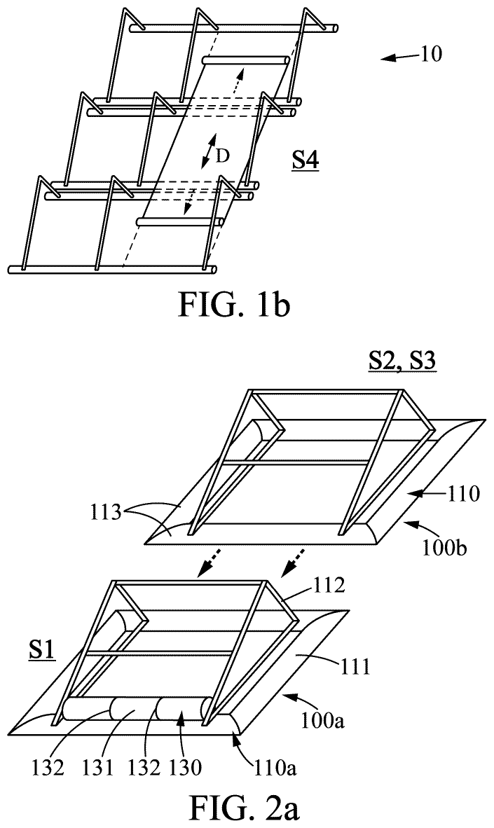

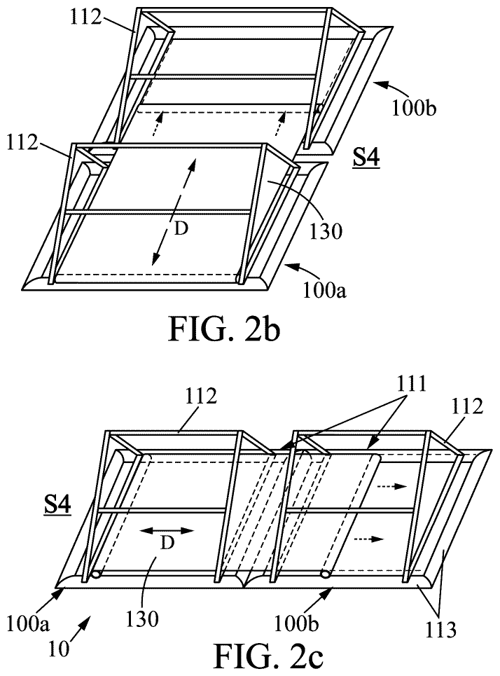

With reference to FIGS. 1a to 2c, we will now describe a method for assembling an electricity production structure 10 comprising several modules 100 assembled together. Structure 10 is adapted to be installed on and to run on a destination aquatic surface: it is therefore able to float.

The aquatic surface can be formed, for example, by a natural or artificial lake, a pond, stored water resources, or even a maritime surface, preferably in a location with low exposure to waves and currents, for example a port, a cove, a lagoon, etc.

Each module 100 is itself able to float on the aquatic surface. It comprises a frame 110 and at least one photovoltaic panel 120 mounted on frame 110. Each module preferably comprises a plurality of photovoltaic panels mounted on the frame, for example between two and ten panels, for example between four and eight panels. The photovoltaic panels of a same module are electrically connected to each other, typically in series.

Frame 110 comprises a base 111 suitable for contact with the aquatic surface and for ensuring flotation of the module, and a support structure 112 to support photovoltaic panels 120, integral with the base, for example mounted thereon.

Base 111 can be formed, for example, of one or more straight and/or curvilinear cylindrical elements 113. Each cylindrical element can be tubular, meaning hollow in its cross-section, to improve flotation of the frame. The cross-section of the cylindrical elements is of any shape, for example circular. Base 111 is preferably made of a material that is light enough to ensure flotation of the module, such as a composite or polymer material, for example polyethylene or PVC. Alternatively, base 111 can also be made of a light and corrosion-resistant metal or metal alloy, for example aluminum or a Zn—Mg—Al alloy.

In one embodiment, of which an example is shown in FIG. 2a, the base is formed of a set of tubular elements connected to each other and defining a closed framework, for example square or rectangular in shape. Optionally, the base may also comprise, within this framework, one or more crosspieces delimiting several closed cells within the framework and stiffening the framework.

In another embodiment, of which an example is shown in FIG. 1a, the base of the frame comprises several parallel cylindrical elements, these elements each being secured to photovoltaic panel support structure 112, and rigidly connected to each other by structure 112.

Support structure 112 is advantageously adapted to keep the photovoltaic panels in a plane forming an angle of between 0 and 40° relative to the plane of the aquatic surface. This angle depends on the installation latitude of the site. For example, for mainland France, this angle is preferably between 25° and 35°, and more advantageously equal to 30°, which corresponds to the position of maximum photovoltaic conversion efficiency. In latitudes closer to the equator, this angle can be smaller, even close to 0°. Support structure 112 is therefore adapted to allow its assembly to the base of the frame, and to form a support surface for the photovoltaic panels, making it possible to attach these panels in the plane of inclination.

In some embodiments, support structure 112 is also adapted to provide an elevation of the photovoltaic panels of at least 20 cm relative to the aquatic surface, the elevation being measured at the lowest point of the photovoltaic panels once they are mounted on structure 112. In some embodiments, the elevation of the panels relative to the aquatic surface can be between 20 cm and 1.50 m depending on the constraints (exposure to wind in particular) related to the installation site of structure 112, and for example between 20 and 50 cm.

The support structure can advantageously be formed of light metal, for example aluminum, or of a composite or polymer material, for example polyethylene or PVC. The support structure can be formed of the same material as the frame base.

In one embodiment, the photovoltaic panel or panels are two-sided, meaning they comprise two main surfaces that are opposite to each other and are covered at least in part with photovoltaic cells suitable for generating electricity from photons via the photovoltaic effect. The two main surfaces are the surfaces of the panel parallel to the plane of inclination of the panels relative to the horizontal as mentioned above. They therefore comprise what is referred to as an upper face, which is oriented towards the sky in order to directly receive the light coming from the sun, and what is referred to as a lower face, which is oriented towards the aquatic surface on which the module is placed, so as to receive photons reflected on a reflective surface such as the aquatic surface or a tarpaulin stretched under the panels.

The structure also comprises at least one tarpaulin 130 fixed to the constituent modules of installation 10 and stretched under the panels, this tarpaulin making it possible to stiffen the installation. Tarpaulin 130 can also be adapted to increase the reflection of light towards the photovoltaic panels, in particular if these panels are two-sided. In such case, the tarpaulin is advantageously highly reflective. For example, it can be white in color, either by being made from a white-colored material or being painted white, or by being made from a reflective material, in particular silver-surfaced, for example Mylar™.

In one advantageous embodiment, each tarpaulin can be capable of supporting, once taut, the weight of at least one operator, so as to allow operators to access the panels for maintenance operations by walking on the tarpaulin(s). In addition, the tarpaulin is advantageously made of a material resistant to an aquatic and possibly marine environment, for example a composite material. In one particular embodiment, the tarpaulin can be formed from a fabric conventionally used for catamaran trampolines. Such a fabric also has a set of through-holes arranged regularly on the surface of the fabric. The through-holes can be made by piercing or can result from adapting the weaving width between the composite fibers. The presence of such holes can allow the transmission of some of the incident light to the aquatic surface located under the tarpaulin, thus preserving the aquatic ecosystem. In particular, the fabrics marketed by the companies SergeFerrari (for example Protect range) or Dickson can be used.

As will be described in more detail below, a tarpaulin 130 is common to several modules, and stretched over frames 110 of at least two different modules 100.

The method for assembling structure 10, described below, can be carried out on land, meaning on a land surface that is not the destination aquatic surface of structure 10, and can comprise launching the structure at the end of implementing this method. Alternatively, and as presented in more detail below, certain steps of the method can be carried out on land, and others directly on the destination aquatic surface. As a variant, the structure can also be operated on a land surface, possibly subject to flooding, so that it can continue to function in the event that the area of operation is flooded.

With reference to FIGS. 1a and 2a, the method for assembling a structure 10 as described above comprises supplying S1 a first module 100a which comprises at least one tarpaulin 130 fixed to its frame. Each tarpaulin has, in a main direction D (shown for example in FIG. 1b), a dimension greater than the length of one side of the frame of the first module. For example, each tarpaulin when deployed can have a rectangular shape, its long side corresponding to the main direction D. In addition, each tarpaulin is fixed to frame 110a of the first module in an initial rolled-up or folded configuration, which makes it possible to easily install the tarpaulin on first module 100 then unrolling or unfolding it in direction D.

In the case where frame 110 is formed of a set of tubular elements assembled together to form a closed framework, the length of the sides of the frame corresponds to the length of the sides of the framework. Tarpaulin 130 then has a dimension, in its main direction D, that is greater than the length of the sides of the framework extending in this direction. In the case shown in FIG. 1a where the base of the frame is formed of a set of tubular elements parallel to each other and connected by the support structure of the modules, the length of the sides of the frame corresponds, for the sides formed by the tubular elements, to the length of these elements, and for the other sides, to the maximum distance between two tubular elements of the base. In the example of FIG. 1a, the base of a frame is formed of two tubular elements parallel to each other, and this maximum length corresponds to the distance between the two tubular elements.

Regarding the initial rolled-up or folded configuration of the tarpaulin, several variants are possible. In an example shown in FIG. 1a, the tarpaulin can comprise a central strip fixed to the frame of the first module, for example to two parallel cylindrical elements 113 of the frame, being stretched between these elements. The two free ends of the tarpaulin are then rolled up into two rolls 131. In another example shown in FIG. 1b, the tarpaulin is fixed to the frame of the first module by one end, and the rest of the length of the tarpaulin all the way to the opposite end is rolled up into one roll 131. According to other possible examples, the tarpaulin can be folded rather than rolled up, for example accordion style, to allow simple deployment. According to yet another example, the tarpaulin can be folded in the main direction and in another direction perpendicular to the first, and deployment of the tarpaulin then comprises the act of unfolding the tarpaulin in a first direction then in the other direction.

Each module may also comprise several tarpaulins rolled up or folded in the same manner and installed side by side on the frame of the module, along a direction perpendicular to the main direction of the tarpaulins. Thus, the number and width of the tarpaulins can be adapted so that the tarpaulins occupy the entire length of the module in the direction perpendicular to the main direction of the tarpaulins. For example, if a module comprises a row of photovoltaic panels assembled side by side, the tarpaulins can be arranged side by side so that the main direction of the tarpaulins is perpendicular to the direction of alignment of the photovoltaic panels. Each tarpaulin can then have a width corresponding to the width of one or more modules. According to one exemplary embodiment, each tarpaulin can have a width substantially equal to that of a photovoltaic panel, so that the module comprises a tarpaulin under each panel. According to another example, each tarpaulin can have a width substantially equal to the width of two photovoltaic panels, so that the module comprises a tarpaulin under two adjacent panels. In FIG. 1a, only one tarpaulin has been shown for the sake of clarity, corresponding to the width of a panel (represented with dotted lines). In FIG. 2a, another example is shown in which a tarpaulin occupies the entire width of the module. In a variant shown in FIG. 2c, the main direction of a tarpaulin can also be parallel to the direction of alignment of the photovoltaic panels of a same row.

The step of supplying 51 this module with a pre-rolled or pre-folded tarpaulin advantageously comprises assembling S10 the frame of the module, and fixing S11 the tarpaulin to the frame of the module with one or more rolled-up or folded ends.

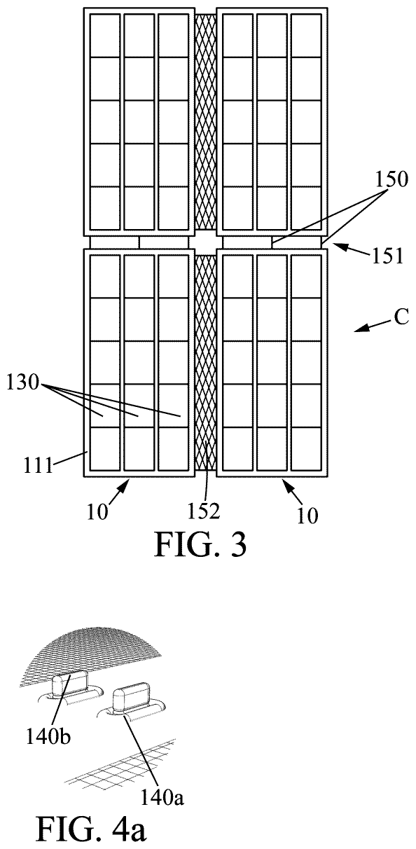

These steps are carried out on land, meaning on a land surface which is not the destination aquatic surface of the floating structure. Temporary fastening means can be positioned to hold the tarpaulin in its initial rolled-up or folded position. For example, in the case where the tarpaulin is rolled up, the temporary fastening means can be collar clips 132 wrapped around each roll of tarpaulin. Alternatively, when the tarpaulin is folded, the temporary fastening means can comprise clamps, elastic straps, or any other appropriate means. The step of supplying the module then comprises a step of installing S12 the panel(s) on the frame of the module, comprising the mechanical attachment of the panels to the frame and the electrical connection of the panels to each other. The panels are only represented with dotted lines in FIG. 1a and FIG. 3 to illustrate their position, but are not shown in the other figures for the sake of clarity.

In one embodiment of the method, this first module is then positioned during a step S13 on the destination aquatic surface, and the step described below of positioning at least one additional module next to the first module is also carried out on this aquatic surface. Alternatively, if the first module is not placed on the destination aquatic surface, the next step is also carried out on land.

The method for assembling electricity production structure 10 then comprises a step S2 of positioning at least one additional module 100b next to first module 100a, along the main direction of the tarpaulin. In one embodiment, the number of additional modules is between 1 and 10, for example between 1 and 5. The positioning of additional module(s) 100b along the main direction of the tarpaulin allows unrolling or deploying the tarpaulin along this direction from its initial configuration allows stretching the tarpaulin over one of the additional modules.

For example, and as shown in FIG. 1a, if the tarpaulin is fixed to the first module with its two free ends rolled up, additional modules can be assembled to the first module on either side of it, as represented by the dotted arrows. According to one non-limiting exemplary embodiment, two additional modules can be assembled one on each side of the first module, and the tarpaulin can have sufficient length to be able to be fixed to the furthest edge of the frames of the two end modules.

According to another example shown in FIG. 2a, if the tarpaulin is attached to the first module by one end of said tarpaulin, additional modules are assembled to the first module on only one side thereof, as represented by the dotted arrows. Advantageously, if the tarpaulin is attached to one edge of the frame of the first module, the additional module(s) can be positioned adjacent to the opposite edge of the frame of the first module, so that, once unrolled, the tarpaulin extends under the panels of the first module and of the additional module(s). For example, to obtain a raft of five modules, four additional modules can be assembled to the first module, and the tarpaulin can have a length equal to the cumulative width of the five modules.

A step S3 then comprises assembling the modules 100 together, comprising a mechanical attachment of the modules to each other, by means known per se, and an electrical connection between the panels of the various modules. At the end of step S3, a raft is therefore obtained by the assembling of several modules. If the raft was assembled on land, this step S3 can optionally be followed by launching S30 the raft onto the destination aquatic surface.

During a step S4, each tarpaulin 130 provided on first module 100a is then unrolled or unfolded to its entire length, and at least one free end of the tarpaulin is fixed to a module 100b other than the first module, which can be a module adjacent to the first module or a module separated from the first module by at least one additional module 100b. The unrolling or unfolding of the tarpaulin can be carried out along the main direction of the tarpaulin. Advantageously, tarpaulin 130 is fixed to an opposite end of the raft, if it has only one free end, or to two opposite ends if it has two free ends. To do this, each free end of the tarpaulin can in particular be fixed to the frame of a module, and more precisely to an element of the base of the frame that is furthest from the first module. Step S4 also comprises tensioning each tarpaulin. Exemplary embodiments of this step are represented in FIGS. 1b, 2b, and 2c, which show a tarpaulin being deployed. In other words, in the representation of FIGS. 1b, 2b, and 2c, tarpaulin 130 is not yet completely deployed and can still be pulled further until it reaches the frame edge or edges where the free end or ends of the tarpaulin will be fixed. FIGS. 1b and 2b correspond to the implementation of step S4 on the rafts obtained after assembling the modules respectively represented in FIGS. 1a and 2a. FIG. 2c shows another exemplary embodiment in which the main direction of the tarpaulin is perpendicular to its direction in FIGS. 1a and 2a, and parallel to the direction of alignment of the photovoltaic panels of a same row.

In order to allow installing the tarpaulin on the first module and fixing it to another module, the tarpaulin and/or the modules can be equipped with fastening devices 140 enabling the tarpaulin to be attached to the modules without requiring holes. Advantageously, the tarpaulin also comprises tensioning devices 141, which can be separate from or combined with the fastening devices. Fastening devices which attach without requiring holes, in particular if they are carried by the tarpaulin, can allow implementing the method for assembling the structure, on modules whose frame has not been specifically provided for this purpose, and without degrading the integrity of the frame.

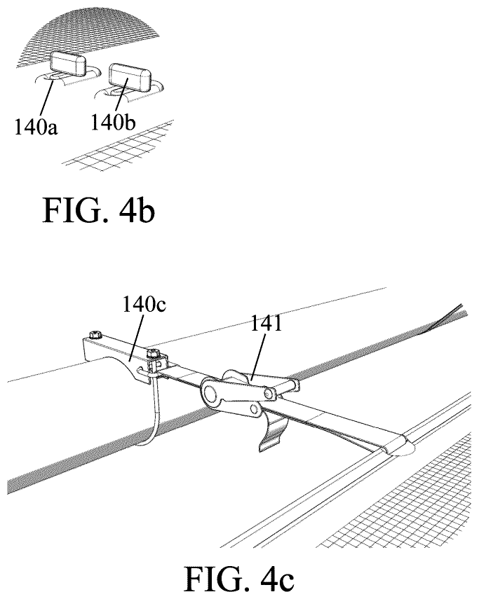

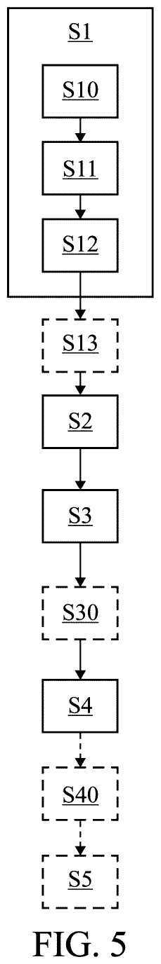

With reference to FIGS. 4a and 4b, the tarpaulin may comprise a set of eyelets 140a into which twist-lock fasteners 140b provided on the modules can be inserted (FIG. 4a) and pivoted (FIG. 4b) in order to retain the tarp.

According to another example shown in FIG. 4c, the tarpaulin can be provided at its ends with U-bolts 140c whose diameter is greater than or equal to the outside diameter of the elements of the frame base, so as to be able to fit around such an element without requiring holes in it.

According to yet other variants, the fastening devices may also comprise hooks or lines provided on the tarpaulin and hasps or brackets provided on the modules, or vice versa.

For these fastening devices, the tarpaulin may comprise separate tensioning devices 141 such as ratchet straps. This is the case shown for example in FIG. 4c where attachment of the tarpaulin on the frame is ensured by U-bolts 140C and its tensioning by ratchet straps 141.

Alternatively, fastening devices with tensioning such as turnbuckles can also be provided.

Once the tarpaulin has been deployed and tensioned, and if structure 10 is still on land, it can be launched during a step S40. However, one will note that it is more advantageous to launch the modules before assembling them and deploying the tarpaulin(s), since launching an assembled structure, possibly large in size, can be more complex to achieve.

Due to the implementation of this method, it is therefore possible to easily assemble several modules together on the aquatic surface, then to deploy the tarpaulin once the modules are assembled on the water. Labor for the installation of a floating structure is therefore reduced, since preparation of the first module with the prepositioned tarpaulin can be carried out beforehand in a factory or on land before launching the modules. The reduced size of each module also facilitates their handling during the phases of launching and assembly on the aquatic surface. In addition, the tarpaulins are not cut into unit areas but are deployed in strips shared by several adjacent modules, which allows reducing the work of cutting, preparation, and attachment to the modules, while increasing the reflection surface area formed by the tarpaulin.

Referring to FIG. 3, it is also possible to assemble (step S5) several of these structures to each other to form a photovoltaic power plant C of large dimensions. The assembly of two adjacent structures 10 can comprise a mechanical attachment of frames of two modules located at the edge of two adjacent structures (the rigid connection parts between two adjacent structures have been schematically represented by reference 150), and an electrical connection of the panels.

Advantageously, one can provide, between two rows of photovoltaic panels of two successive structures, a line of water 151 which is devoid of tarpaulins, and which thus allows some light to travel into the water to reduce the impact of the power plant on the underwater life. Optionally, a grating 152 can also be provided between two adjacent structures along the direction of the rows of photovoltaic panels, to allow easy access to the panels for maintenance, servicing, or repair operations. The grating can be adapted to rigidly connect the structures 10 together while leaving a space that is the width of the grating, for the movement of operators. The use of a tarpaulin made of catamaran trampoline fabric can replace these gratings, however.

1-14. (canceled)

15. A method for assembling an electricity production structure capable of being installed on a destination aquatic surface, comprising a plurality of modules capable of floating, each module comprising a frame and at least one photovoltaic panel mounted on the frame, the structure further comprising at least one tarpaulin stretched under the photovoltaic panels of at least two adjacent modules, the method comprising:
supplying a first module comprising at least one tarpaulin fixed thereto, the tarpaulin having a length, in a main direction, that is greater than the length of one side of the frame of the first module, and being fixed to said frame in an initial folded or rolled-up configuration enabling deployment of a length of the tarpaulin at least in the main direction starting from said initial configuration,
positioning at least one additional module adjacent to the first module in the main direction of the tarpaulin,
assembling the additional module to the first module, and
deploying and fixing each tarpaulin of the first module to the frame of a module other than the first module, and tensioning each tarpaulin.

16. The method according to claim 15, further comprising installing the first module on the aquatic surface, the steps of positioning, assembling at least one additional module, and deploying each tarpaulin being carried out on said aquatic surface.

17. The method according to claim 15, further comprising installing on the aquatic surface the structure obtained after tensioning each tarpaulin, or installing the assembly of the first module and of each additional module on the aquatic surface before each tarpaulin is deployed.

18. The method according to claim 15, wherein, in the initial configuration, the tarpaulin comprises a central strip fixed to the first module and the two ends of the tarpaulin are rolled up or folded, and the method comprises assembling at least one additional module on each side of the first module in the main direction of the tarpaulin, deploying each end of the tarpaulin, and fixing each end of the tarpaulin to a respective module.

19. The method according to claim 15, wherein the attachment of a tarpaulin to the frame of a module is carried out without requiring holes in the frame.

20. The method according to claim 15, wherein the first module comprises several tarpaulins fixed next to each other in a direction perpendicular to the main direction of each tarpaulin, and the method comprises deploying each of the tarpaulins in the common main direction of the tarpaulins.

21. A electricity production structure capable of being installed on a destination aquatic surface, comprising a plurality of modules assembled to each other, each module being capable of floating on an aquatic surface and comprising a frame and at least one photovoltaic panel mounted on the frame,
the structure further comprising at least one tarpaulin stretched under photovoltaic panels of at least two adjacent modules, the ends of each tarpaulin being fixed to different modules.

22. The electricity production structure according to claim 21, wherein the tarpaulin is reflective.

23. The electricity production structure according to claim 21, wherein each photovoltaic panel comprises two electricity-producing faces which are opposite to each other.

24. The electricity production structure according to claim 21, wherein each tarpaulin is capable of supporting the weight of at least one operator.

25. The electricity production structure according to claim 21, wherein each tarpaulin is formed from a fabric comprising a set of regularly distributed through-holes adapted to transmit part of the light that is incident on the fabric.

26. A floating structure according to claim 21, wherein each tarpaulin and/or each module comprises fastening devices for fixing a tarpaulin to a frame without requiring holes, or tarpaulin tensioning devices.

27. A floating photovoltaic power plant, comprising at least two structures according to claim 21, assembled together.

28. A electricity production module able to float on an aquatic surface, the module comprising a frame, at least one photovoltaic panel mounted on said frame, and at least one tarpaulin fixed on the frame, the tarpaulin having a length, in a main direction, that is greater than the dimension of one side of the frame, being fixed to said frame in a folded or rolled-up configuration enabling deployment of a length of the tarpaulin in said main direction starting from said configuration.
